(19) United States
(12) Patent Application Publication
(10) Pub. No.: US 2013/0161825 A1
(43) Pub. Date: Jun. 27, 2013

(54) THROUGH SUBSTRATE VIA STRUCTURE AND METHOD FOR FABRICATING THE SAME

(71) Applicants: TZU-CHIEN HSU, Hsinchu County (TW); Tzu-Kun Ku, Hsinchu City (TW); Cha-Hsin Lin, Miaoli County (TW)

(72) Inventors: TZU-CHIEN HSU, Hsinchu County (TW); Tzu-Kun Ku, Hsinchu City (TW); Cha-Hsin Lin, Miaoli County (TW)

(73) Assignee: INDUSTRIAL TECHNOLOGY RESEARCH INSTITUTE, Hsinchu (TW)

(21) Appl. No.: 13/341,846

(22) Filed: Dec. 30, 2011

(30) Foreign Application Priority Data
Dec. 26, 2011 (TW) TW100148545

(51) Int. Cl. H01L 23/48; H01L 21/768

(52) U.S. Cl. 257/774; 438/667; 257/E23.011; 257/E21.577

(57) ABSTRACT

A through substrate via (TSV) structure is provided, including: a substrate; an opening formed in a portion of the semiconductor substrate; a dielectric layer formed on the sidewall of the opening; a conductive pillar formed inside the opening; and at least a portion of the dielectric layer is removed to form void. Also provided is a method for fabricating a through substrate via (TSV) structure.

### CROSS REFERENCE TO RELATED APPILCATIONS

This present Application claims priority of Taiwan Patent Application No. 100148545, filed on Dec. 26, 2011, the entirety of which is incorporated by reference herein.

### BACKGROUND

1. Technical Field

The present disclosure relates to semiconductor fabrication, and in particularly to a through substrate via (TSV) structure and a method for fabricating the same.

2. Related Art

A through substrate via (TSV) is a vertical electrical connection through a silicon wafer or die, and TSV technology is important in creating 3-dimensional (3D) packages and 3D integrated circuits (3D ICs).

A 3D package, e.g. system in package, chip stack multi-chip module (MCM), etc., contains two or more chips (integrated circuits) stacked vertically so that they occupy less space.

In most 3D packages, the TSV is formed through a chip and functions as a vertical connector, such that a length or a width of an obtained package will not be increased. Due to absence of interconnect components, the 3D package using the TSV can be provided with a more planar configuration.

A 3D integrated circuit (3D IC) is a single integrated circuit built by stacking silicon wafers and/or dies and interconnecting them vertically so that they are packaged as a single device. By using TSV technology, 3D ICs can pack a great deal of functionality into a small footprint. In addition, critical electrical paths through the device can be drastically shortened, leading to a faster operation.

Accordingly, a reliable through substrate via (TSV) structure and a method for fabricating the same are desired for the above 3D packages and 3D ICs applications.

### SUMMARY

An exemplary through substrate via (TSV) structure comprises: a substrate; an opening formed in the substrate; a dielectric layer on a sidewall of the opening; a conductive pillar formed inside the opening; and at least a portion of the dielectric layer is removed to form void.

An exemplary method for fabricating a through substrate via (TSV) structure comprises: providing a substrate; forming an opening in the substrate; forming a dielectric layer in the opening; forming a conductive pillar inside the opening formed with the dielectric layer; and removing at least a portion of the dielectric layer to form void.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1-15 are schematic diagrams showing a method for fabricating a through substrate via (TSV) structure according to an embodiment of the disclosure, wherein FIGS. 1, 3, 5, 7, 9, 11, and 13 are schematic top views, and FIGS. 2, 4, 6, 8, 10, 12, 14, and 15 are schematic cross sections;

FIGS. 16-17 show a TSV structure according to another embodiment of the disclosure;

FIG. 18 shows a TSV structure according to yet another embodiment of the disclosure; and

FIG. 19-22 are schematic diagrams showing a method for fabricating a through substrate via (TSV) structure according to another embodiment of the disclosure, wherein FIGS. 19 and 21 are schematic top views, and FIGS. 20 and 22 are schematic cross sections.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

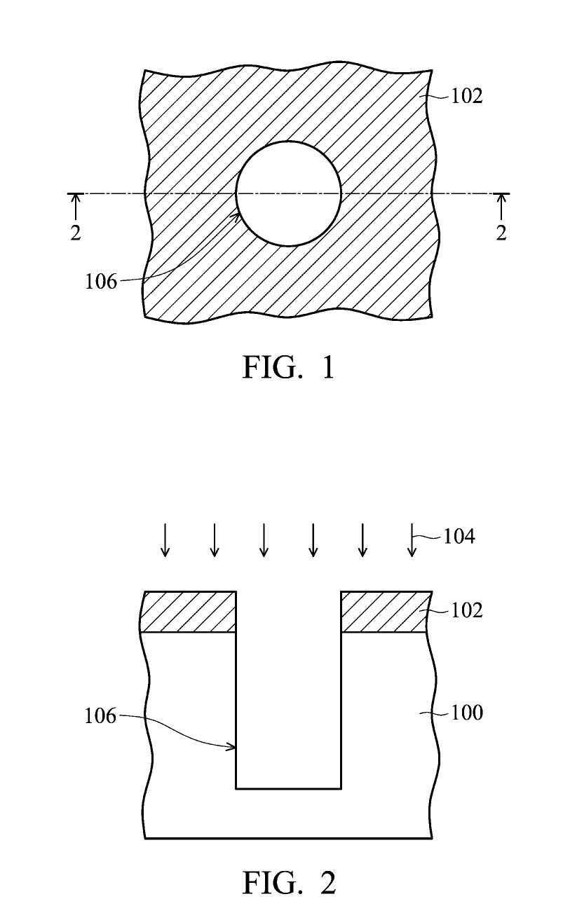

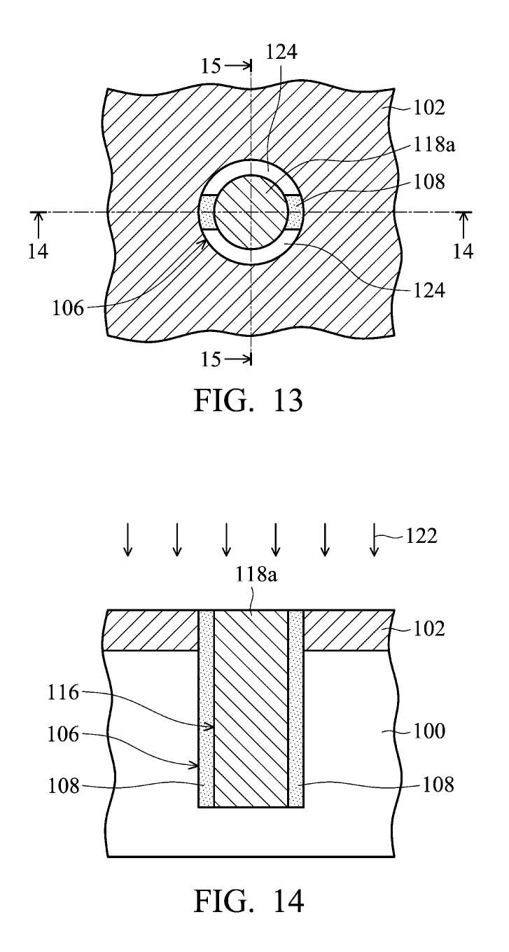

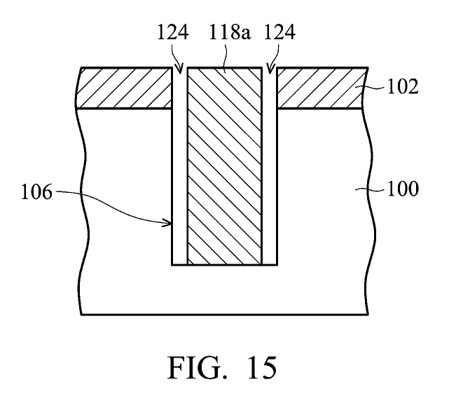

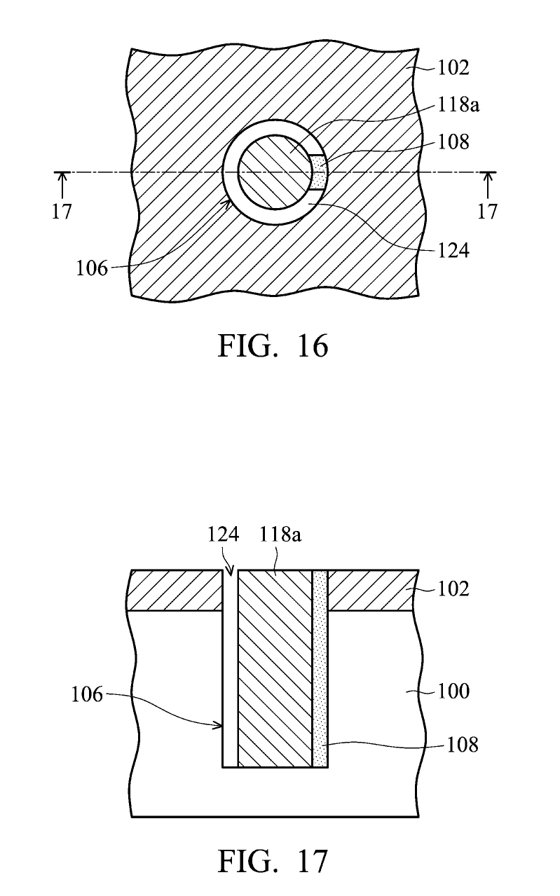

FIG. 1-15 are schematic diagrams showing an exemplary method for fabricating a through substrate via (TSV) structure, wherein FIGS. 1, 3, 5, 7, 9, 11, and 13 are schematic top views, and FIGS. 2, 4, 6, 8, 10, 12, 14, and 15 are schematic cross sections taken along a line 2-2, line 4-4, line 6-6, line 8-8, line 10-10, line 12-12, line 14-14, and line 15-15 in FIGS. 1, 3, 5, 7, 9, 11, and 13, respectively.

In FIGS. 1 and 2, a substrate 100 with a dielectric layer 102 formed there over is first provided. Herein, for the purpose of simplicity, only a portion of the substrate 100 and the dielectric layer 102 is illustrated. However, other components (not shown) such as active devices, positive devices, and/or interconnect elements may be formed on/in the substrate 100 and on/in the dielectric layer 102, and these components are not shown in FIGS. 1-2. The substrate 100 can be a semiconductor substrate, such as a bulk semiconductor substrate, and the dielectric layer 102 may comprise dielectric materials such as silicon oxide, silicon nitride or other suitable dielectric materials. In other embodiments, the substrate may comprise silicon, germanium, gallium arsenide (GaAs), silicon carbide (SiC), gallium nitride (GaN) or other semiconductor materials, or may comprise insulating materials such as ceramic, glass, or organic polymers.

Next, a patterning process 104 comprising a photolithography step and an etching step (both not shown) is performed to form an opening 106 in a portion of the substrate 100 and the dielectric layer 102. As shown in FIG. 2, the opening 106 is formed through the dielectric layer 102 and is formed in a portion of the substrate 100.

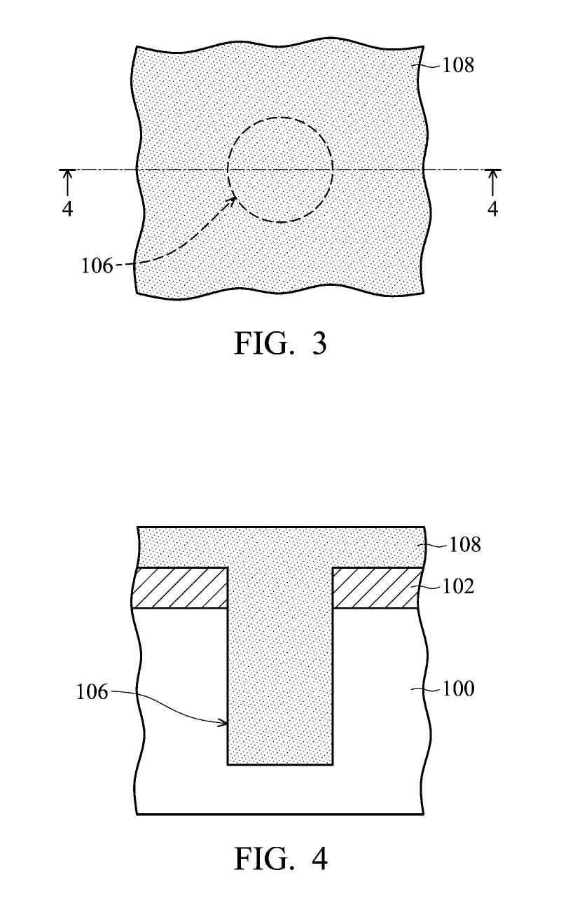

In FIGS. 3-4, a dielectric layer 108 is blanketly formed over the substrate 100 and the dielectric layer 102, filling the opening 106. The dielectric layer 108 can be formed by, for example, spin coating, such that the dielectric layer 108 is formed with a planar surface after formation thereof. Herein, the dielectric layer 108 may comprise dielectric materials different from that of the dielectric layer 102, and preferably comprises low dielectric constant (low-k) dielectric materials having a dielectric constant less than 3.9, such as benzocyclobutene (BCB, k=2.64).

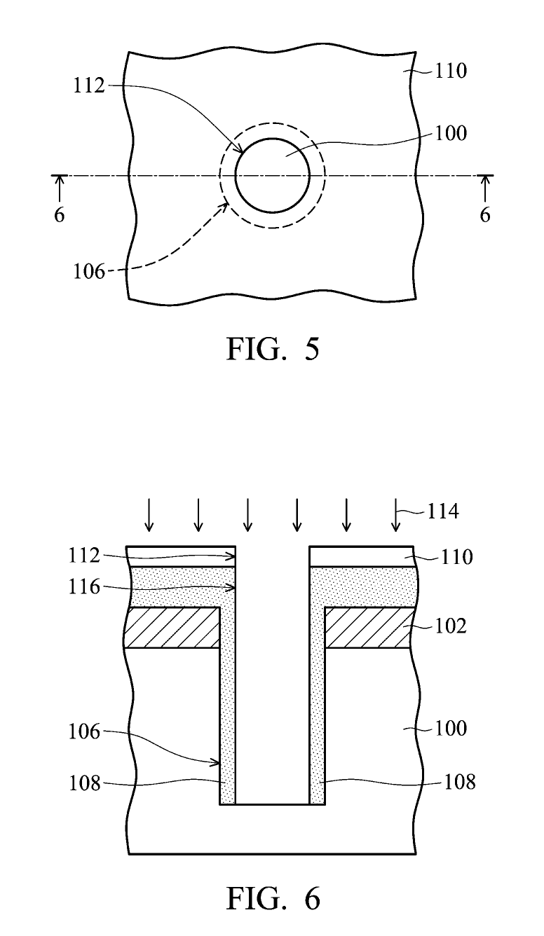

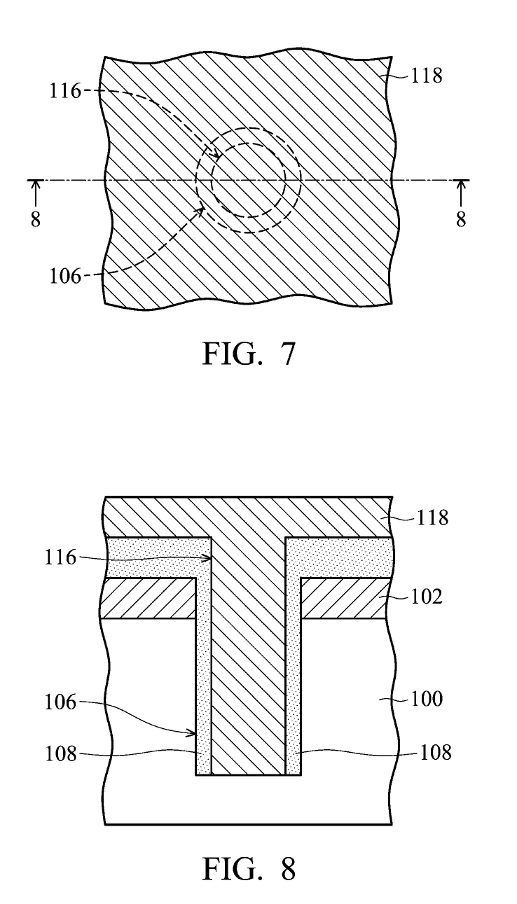

In FIGS. 5-6, a patterned dielectric layer 110 with an opening 112 therein is formed over the dielectric layer 108. Herein, the patterned dielectric layer 110 blanketly covers the dielectric layer 108 and the opening 112 exposes a portion of the dielectric layer 108 in the opening 106. Next, an etching process 114 is performed, using the patterned dielectric layer 110 as an etching mask, to remove the portion of the dielectric layer 108 exposed by the opening, thereby forming an opening 116 in the dielectric layer 108. The opening 116 exposes a portion of the substrate 100, and a patterned dielectric layer 108 with a ring-shaped top view is formed in the opening 106. The patterned dielectric layer 110 may comprise dielectric materials different from that of the dielectric layer 108, such as silicon oxide, and silicon nitride. Herein, the etching process 114 can be, for example, a wet etching process or a dry etching process.

In FIGS. 7-8, after removing the patterned dielectric layer 110, a conductive layer 118 is blanketly formed over the dielectric layer 108, filling the opening 116. The conductive layer 118 can be a copper layer, and can be formed by, for example, an electroplating process. In addition, when the conductive layer 118 is a copper layer, an optional conductive barrier layer (not shown) may be formed between the conductive layer 118 and the substrate 100 and the dielectric layer 108 to prevent copper diffusion issues of the conductive layer 118.

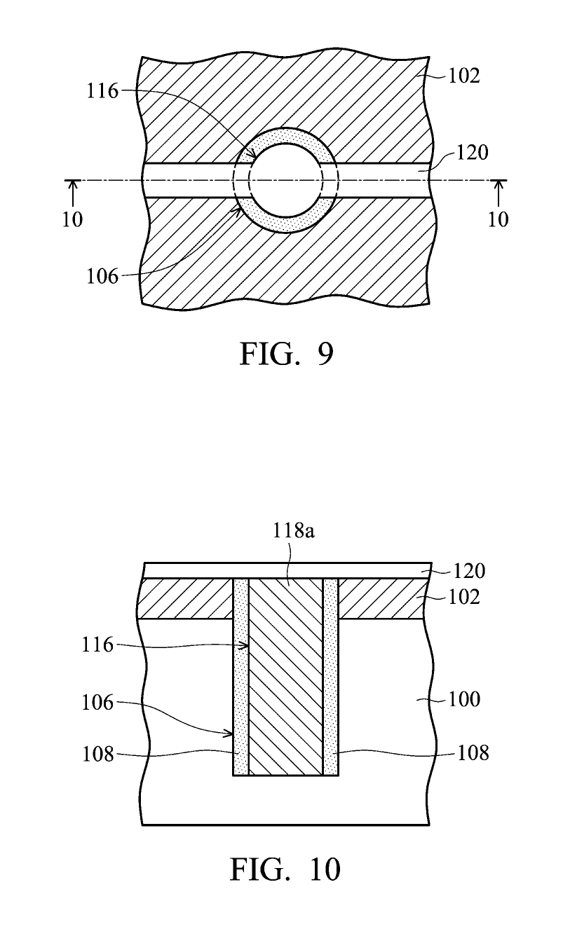

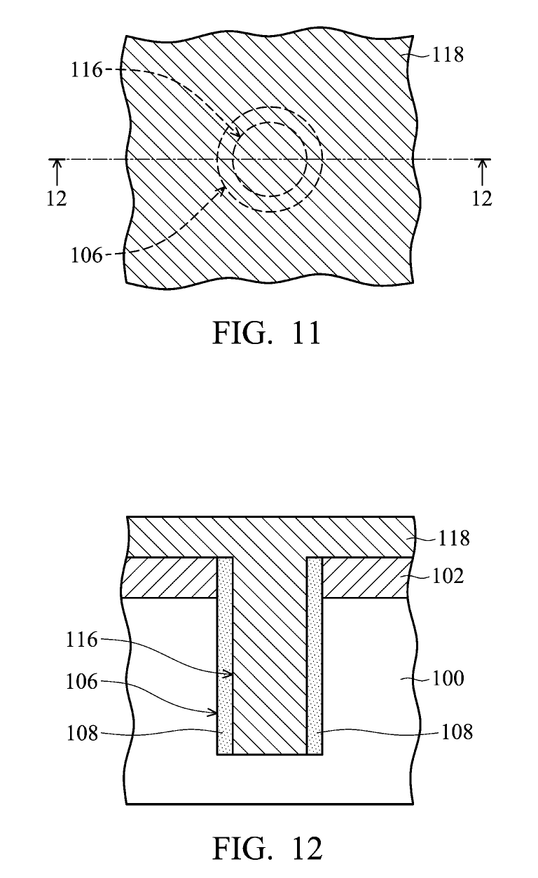

In FIGS. 9-10, a planarization process (not shown), such as a chemical mechanical polishing (CMP) process is performed to remove the dielectric layer 108 and the conductive layer 118 above the dielectric layer 102, thereby leaving the dielectric layer 108 and a conductive pillar 118a which are coplanar with the dielectric layer 102 in the opening 106. Herein, the dielectric layer 108 surrounds a sidewall of the conductive pillar 118a and isolates the conductive pillar 118a from the substrate 100 and the dielectric layer 102 adjacent thereto. Next, a patterned dielectric layer 120 is formed, partially covering the dielectric layer 102 and the dielectric layer 108, and entirely covering the conductive pillar 118a, thereby exposing a portion of the dielectric layer 108 in the opening 106. Herein, the dielectric layer 120 may comprise dielectric materials different from that of the dielectric layer 120, such as silicon oxide or silicon nitride.

In FIGS. 11-12, in another embodiment, prior to formation of the conductive layer 118, the dielectric layer 108 above the dielectric layer 102 can be simultaneously removed during removal of the patterned dielectric layer 110, and the dielectric layer 108 and the conductive pillar 118a in the opening 106 which are coplanar with the dielectric layer 102 are then formed by the fabrication steps disclosed in FIGS. 9-10. Next, according to the fabrication steps disclosed in FIGS. 9-10, a patterned dielectric layer 120 is formed to partially cover the dielectric layer 102 and the dielectric layer 108, and entirely covers the conductive pillar 118a, thereby partially exposing a portion of the dielectric layer 108 in the opening 106. Herein, the dielectric layer 120 may comprise dielectric materials different from that of the dielectric layer 108, such as silicon oxide or silicon nitride.

In FIG. 13-15, an etching process 122 is performed to remove the portion of the dielectric layer 108 in the opening 106 which is exposed by the patterned dielectric layer 120, thereby forming a plurality of voids 124 in the opening 106. Herein, the etching process 122 can be, for example, a dry etching process or a wet etching process. Next, an etching process (not shown) is performed to remove the patterned dielectric layer 120, thereby obtaining a through substrate via (TSV) structure shown in FIGS. 13-15. Next, other fabrication steps (not shown) can be further performed to form other components over the dielectric layer 102, and the substrate 100 is then thinned from a surface without the dielectric layer 102 to expose an end of the conductive pillar 118a of the TSV structure, such that electrical connections are provided with other substrates.

As shown in FIGS. 13-15, the dielectric layer 108 is respectively formed on opposing sidewalls of the conductive pillar 118a, and each of the dielectric layers 108 extends from a top portion to a bottom portion in the opening 106, thereby providing structural supports for the conductive pillar 118a from a side thereof. Moreover, a void 124 is formed in the other two sides of the conductive pillar 118a, comprising only air but no dielectric material, such that the void 124 may have a low-k value of about 1. Further, since the dielectric layer 108 can also be a low-k dielectric layer, a parasitic capacitance of the TSV structure shown in FIGS. 13-15 can be thus reduced while a mechanical strength thereof is also maintained, thereby having improved reliability after performing sequential semiconductor processes.

In addition to the fabrication steps disclosed in FIGS. 13-15, the patterned dielectric layer 120 shown in FIGS. 9-10 may be properly modified to obtain various embodiments of the TSV structure shown in FIGS. 16-18. The TSV structure shown in FIGS. 16-18 may still have the same advantages as that of the TSV structure shown in FIGS. 13-15.

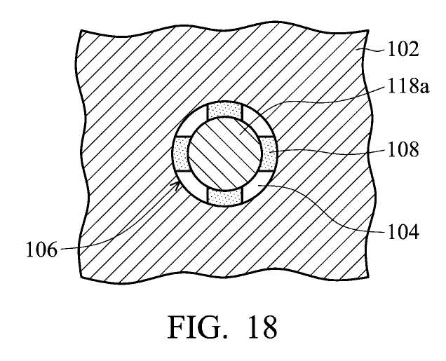

In FIGS. 16-17, in one embodiment, a dielectric layer 108 is merely formed on a portion of the sidewall of the conductive pillar 118a, and the dielectric layer 108 extends from a top portion to a bottom portion in the opening 106, thereby providing structural supports from a side of the conductive pillar 118a, and other portions of the sidewall of the conductive pillar 118a is surrounded by a void 124. Moreover, as shown in FIG. 18, in another embodiment, a dielectric layer 108 is formed on a plurality portions of the sidewall of the conductive pillar 118a, and the dielectric layer 108 extends from a top portion to a bottom portion in the opening 106, thereby providing structural supports to sidewalls of the conductive pillar 118a, wherein several portions of the sidewall of the conductive pillar 118a is respectively surrounded by a void 124.

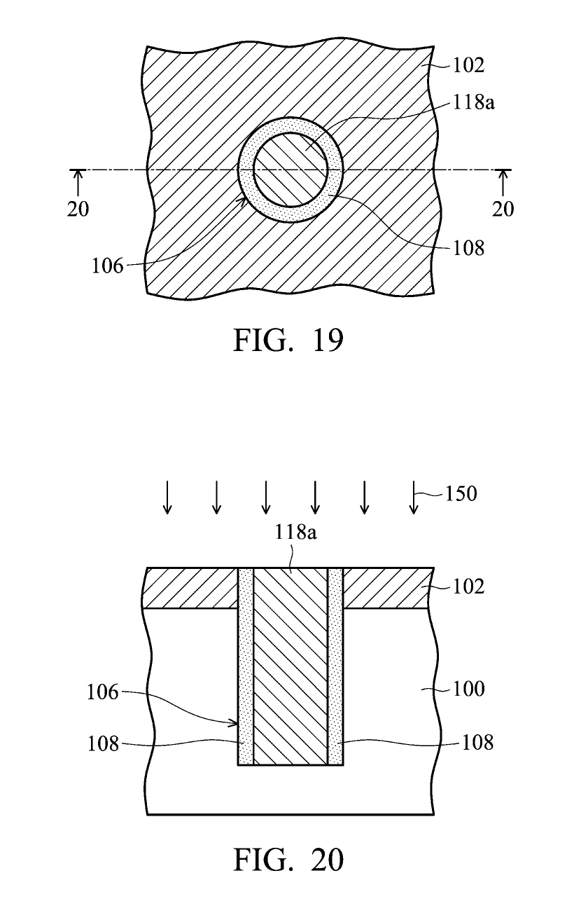

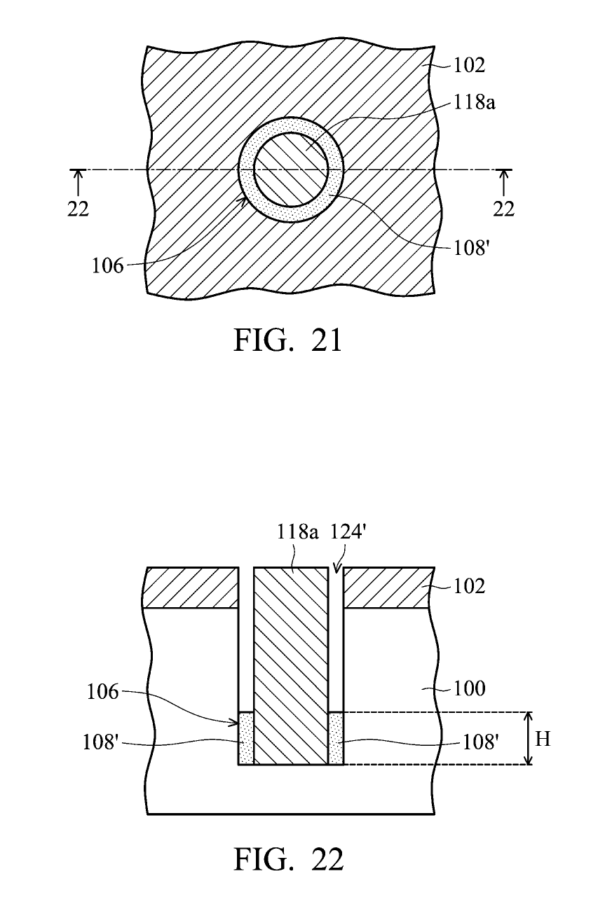

FIG. 19-22 are schematic diagrams showing anther exemplary method for fabricating a through substrate via (TSV) structure, wherein FIGS. 19 and 21 are schematic top views, and FIGS. 20 and 22 are schematic cross sections.

In FIGS. 19-20, a structure fabricated by the fabrication steps disclosed in FIGS. 1-8 is first provided, and a planarization process (not shown), such as a chemical mechanical polishing (CMP) process is then performed to remove the dielectric layer 108 and the conductive layer 118 above the dielectric layer 102, thereby leaving the dielectric layer 108 and the conductive pillar 118a coplanar with the dielectric layer 102 in the opening 106. Herein, the dielectric layer 108 surrounds the sidewall of the conductive pillar 118a and isolates the conductive pillar 118a from the substrate 100 and the dielectric layer 102 adjacent thereto.

Next, a removing process 150 is performed to partially remove the dielectric layer 108 in the opening 106, thereby forming the TSV structure as shown in FIGS. 21-22.

In one embodiment, the removing process 150 can be, for example, a dry etching process or a wet etching process, or using exposure and development processes for benzocyclobutene, and may be controlled by time-mode etching, thereby obtaining the TSV structure shown in FIGS. 21-22. Next, other fabrication steps (not shown) can be further performed to form other components over the dielectric layer 102, and the substrate 100 is then thinned from a surface without the dielectric layer 102 to expose an end of the conductive layer 118 of the TSV structure, such that electrical connections are provided with other substrates. In addition, another wet etching (not shown) may be performed to remove native oxide (not shown) which may be formed over the conductive pillar 118a to prevent surface oxidations from happening on the surface of the conductive pillar 118a during the removing process 150.

As shown in FIGS. 21-22, in one embodiment, the dielectric layer 108 in the opening 106 is partially removed, leaving a dielectric layer 108′ located at a bottom portion of the opening 106 and a void 124′ in other portions of the opening 106. Herein, the dielectric layer 108′ fully surrounds a lower portion of the sidewall of the conductive pillar 118a, and other portions of the sidewall of the conductive pillar 118a in the opening 106 is surrounded by the void 124. A distance H between a top surface of the dielectric layer 108′ to a bottom surface of the opening 106 is about 0.1-99.9% of a height of the opening 106.

As shown in FIGS. 21-22, the dielectric layer 108′ is formed on a lower portion of the sidewall of the conductive pillar 118a and surrounds the conductive pillar 118a, thereby providing structural supports for the conductive pillar 118a from the sidewall thereof. Moreover, a void 124 is formed in other portions of the sidewall of the conductive pillar 118a not surrounded by the dielectric layer 108′. Therefore, a parasitic capacitance of the TSV structure shown in FIGS. 21-22 can thus be reduced while a mechanical strength thereof is also maintained; thereby having improved reliability after performing sequential semiconductor processes.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A through substrate via (TSV) structure, comprising:
a substrate;
an opening formed in the substrate;
a conductive pillar formed inside the opening; and
a dielectric layer on a sidewall of the opening, wherein the dielectric layer extends from a top portion to a bottom portion of the opening to support the conductive pillar.

2. The TSV structure as claimed in claim 1, wherein the dielectric layer comprises dielectric materials having a dielectric constant less than 3.9.

3. The TSV structure as claimed in claim 1, wherein the dielectric layer comprises benzocyclobutene.

4. (canceled)

5. (canceled)

6. The TSV structure as claimed in claim 1, wherein the conductive pillar is a copper layer.

7. The TSV structure as claimed in claim 1, further comprising a plurality of dielectric layers in the opening, respectively disposed between a portion of the sidewall of the conductive pillar and the substrate to support the conductive pillar, wherein the dielectric layers respectively extend from a top portion to a bottom portion of the opening to support the conductive pillar.

8. The TSV structure as claimed in claim 7, further comprising a plurality of voids in the opening, respectively disposed between the dielectric layers to isolate the sidewall of the conductive pillar from the substrate.

9. The TSV structure as claimed in claim 7, wherein the dielectric layers are formed between opposing portions of the sidewall of the conductive pillar and the substrate.

10. The TSV structure as claimed in claim 7, wherein the voids are formed between opposing portions of the sidewall of the conductive pillar and the substrate.

11. A method for fabricating a through substrate via (TSV) structure, comprising:
providing a substrate;
forming an opening in the substrate;
forming a dielectric layer in the opening,
forming a conductive pillar inside the opening formed with the dielectric layer;
removing at least a portion of the dielectric layer to form a void, wherein the dielectric layer remaining in the opening extends from a top portion to a bottom portion of the opening and contacts a portion of the sidewall of the conductive pillar to support the conductive layer.

12. The method as claimed in claim 11, wherein the dielectric layer comprises dielectric materials having a dielectric constant less than 3.9.

13. The method as claimed in claim 12, wherein the dielectric layer comprises benzocyclobutene.

14. (canceled)

15. (canceled)

16. The method as claimed in claim 11, wherein the conductive pillar is a copper layer.

17. The method as claimed in claim 11, wherein the dielectric layer is removed by a removing process.

18. The method as claimed in claim 17, wherein the removing process is a dry etching process or a wet etching process.

19. The method as claimed in claim 11, wherein the dielectric layer remaining in the opening contacts a plurality of opposing portions of the sidewall of the conductive pillar to support the conductive layer.
